(19) United States
(12) Patent Application Publication
(10) Pub. No.: US 2005/0175907 A1
(43) Pub. Date: Aug. 11, 2005

(54) Photo mask including scattering bars and method of manufacturing the same

(76) Inventor: Ji-soong Park, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/051,461

(22) Filed: Feb. 7, 2005

(30) Foreign Application Priority Data
Feb. 11, 2004 (KR) 04-8937

(51) Int. Cl. G03F 9/00; G03C 5/00

(52) U.S. Cl. 430/5; 430/322; 430/311; 430/312; 430/313

(57) ABSTRACT

A photo mask includes a transparent substrate, a main pattern, and scattering bars. The image of the main pattern is that which is transferred to photosensitive material by rays of exposure light transmitted by the photo mask during a photolithographic process. The scattering bars are formed by etching the transparent substrate and the image of the scattering bars is not transferred to the photosensitive material by the exposure light. Each of the scattering bars is formed to such a width and depth as to improve normalized image log slope (NILS) of an aerial image of the rays that have been transmitted by the photo mask.

### BACKGROUND OF THE INVENTION

1. Field of the Invention

The present invention relates to a photo mask. More particularly, the present invention relates to a photo mask having a transparent substrate, and scattering bars formed on the transparent substrate.

2. Description of the Related Art

In recent years, integrated circuit (IC) devices have become highly integrated and highly efficient. This has been achieved, in part, by making the size of features the IC device smaller and smaller. To this end, a photolithography process is used. In photolithography, the image of a pattern of a photo mask is transferred to a photoresist layer on a substrate to form features of an IC device. Therefore, refinements to the photolithography process have been sought as ways to improve the integration density and performance of IC devices and reduce the size of the features thereof. For example, the patterns of photo masks are being scaled down to meet the demand for IC device features having a fine critical dimension (CD).

However, the scaling down of patterns of photo masks has given rise to an optical proximity effect (OPE). Basically, the scale of the pattern of a photomask poses a limit on the resolution of the photolithography exposure process due to the OPE. In particular, variations in the density of a minute pattern of a photo mask often result in the transferring of an image that is distorted, especially in the case of an image that is being used to produce an isolated feature of an IC device. To solve these problems, the resolution of the exposure process may be enhanced using a lens having a high numerical aperture (NA), or the contrast of the image being transferred may be enhanced using a phase shift mask (PSM) as the photo mask. Furthermore, it is possible to enhance the resolution using an off-axis illumination (OAI) system. However, these techniques are limited in their ability to provide a process margin sufficient for mass production.

Another technique used to prevent the image of an isolated feature from being distorted is to use a photo mask having scattering bars. Scattering bars are formed on both sides of a line type of isolated pattern, outside a contact type of isolated pattern, or outside outermost features of a dense pattern (an isolated pattern or a dense pattern will be referred to hereinafter as a main pattern). Each of the scattering bars includes only a single element or a plurality of fine elements. Although the scattering bars are formed on a photo mask along with the main pattern of the photomask, the image of the scattering bars is not transferred during the exposure process because the scattering bars are smaller than the resolution limit of the exposure process.

FIG. 1 is a cross-sectional view of a portion of a photo mask having scattering bars. The photo mask 100 includes a transparent substrate 110, a line type of main pattern 112, and scattering bars 114 formed on both sides of the main pattern 112. The transparent substrate 110 is formed of quartz. The main pattern 112 and the scattering bars 114 may be formed of a metal having a transmissivity of 0%, such as chromium (Cr), or a material having a transmissivity of several to several tens of %, such as molybdenum silicide (MoSi). The width w₂ of the scattering bar 114 is preferably as small as possible to prevent the image of the scattering bar 114 from being transferred to a resist during the photolithography process. That is, the width w₂ of the scattering bar 114 should be less than resolution limit such that an image of the scattering bar 114 is not transferred during an exposure process. As a general rule, the width w₂ of each scattering bar 114 should be less than ½ the width we of the main pattern 112.

However, when a photo mask of this type is used to form a line type of feature of an IC device that is extremely small, i.e., a line type of feature having a small line width, the main pattern 112 must be very narrow. In this case, the width w₂ of the scattering bar 114, which should be less than ½ the width w₁ of the main pattern 112, is extremely small. Obviously, it is very difficult to fabricate scattering bars having extremely small widths.

Further, a scattering bar 114 having a small width w₂ is structurally unstable and thus is very likely to collapse. This phenomenon is illustrated in FIG. 2, which is a scanning electronic microscope (SEM) of a conventional photo mask. Referring to FIG. 2, the scattering bar 124 formed on the left side of a main pattern 122 can be seen leaning towards the main pattern 122. The phenomenon becomes more pronounced as the main patterns of photo masks are scaled down.

### SUMMARY OF THE INVENTION

An object-of the present invention is to provide a photo mask having scattering bars that are relatively easy to manufacture.

Another object of the present invention is to provide a photo mask having scattering bars whose form remains intact throughout and after the course of their manufacture.

Yet another object of the present invention is to provide a photo mask characterized in that the value of the normalized image log slope (NILS) of the aerial image of the rays transmitted by the mask is relatively high.

According to one aspect of the present invention, the photo mask has scattering bars constituted by recesses in or protruding portions of the transparent substrate. The scattering bars are dimensioned so that the destructive interference which occurs when light passes through the photomask prevents an image of the scattering bars from being transferred to photosensitive material (such as a layer of photoresist on a wafer). The phase difference is less than 180°. Preferably, the phase difference is 150° or less and, more preferably, within a range of 30 to 150°. Thus, the value of the normalized image log slope (NILS) of an aerial image of rays that are transmitted is relatively large.

The photo mask may be a binary mask (BM) in which the main pattern is formed of chromium (Cr), a phase shift mask (PSM) in which the main pattern is formed of molybdenum silicide (MoSi), or a chromeless phase lithography (CPL) mask in which the main pattern is formed by etching the transparent substrate. Also, the main pattern may be a line type of isolated pattern, in which case the scattering bars are formed on both sides of the main pattern. Alternatively, the main pattern may be a dense pattern of elements that include line type of elements at outer portions of the dense pattern. In this case, each of the scattering bars may be formed adjacent a respective one of the outermost line type of elements of the main pattern. Each of the scattering bars may be consist of a single pattern element. Furthermore, the width of each of the scattering bars may be ½ to 1 times the width of the main pattern.

According to another aspect of the present invention, a method of manufacturing a photomask includes forming a main pattern at an intermediate region of a transparent substrate, and etching the substrate to form scattering bars at opposite sides of the intermediate region. The main pattern has an image dedicated to be transferred to photosensitive material by rays of exposure light transmitted by the photomask during a photolithography process. The etching of the substrate is carried out so that the scattering bars have dimensions, e.g., widths and either a depth or height, that cause a moderated destructive interference to occur when light is transmitted by the mask. Again, the moderated destructive interference prevents the image of the scattering bars from being transferred to the photosensitive material by the rays of the exposure light transmitted by the photomask during the photolithography process. The scattering bars are also dimensioned by the etching process so that the phase difference—between the rays of the exposure light transmitted through the photo mask at the region of the scattering bars and the rays of the exposure light transmitted through the mask at the intermediate region where the main pattern is located—is less than 180°.

### BRIEF DESCRIPTION OF THE DRAWINGS

The above and other objects, features and advantages of the present invention will become more apparent from the following detailed description of the preferred embodiments thereof made with reference to the attached drawings, in which:

FIG. 1 is a cross-sectional view of a conventional photo mask having scattering bars;

FIG. 2 is a scanning electronic microscope (SEM) of a conventional photo mask having a collapsed scattering bar;

FIG. 3 is a cross-sectional view of an embodiment of a photo mask having scattering bars according to the present invention;

FIGS. 4A and 4B are graphs showing the relative intensity of an aerial image formed using the photo mask shown in FIG. 3 and the relative intensity of an aerial image formed using the conventional mask shown in FIG. 1;

FIG. 5 is a cross-sectional view of another embodiment of a photo mask having scattering bars according to the present invention; and

FIG. 6 is a cross-sectional view of still another embodiment of a photo mask having scattering bars according to the present invention.

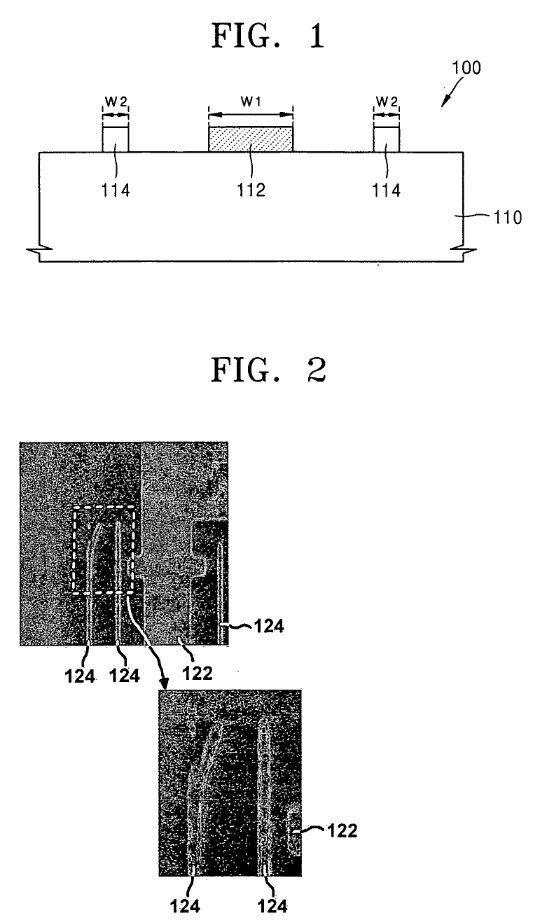

### DETAILED DESCRIPTION OF THE PREFERRED EMBODIMENTS

The present invention will now be described more fully with reference to the accompanying drawings. In the drawings, the thicknesses of layers may be exaggerated for clarity. Also, like reference numerals are used to denote the same elements throughout the drawings.

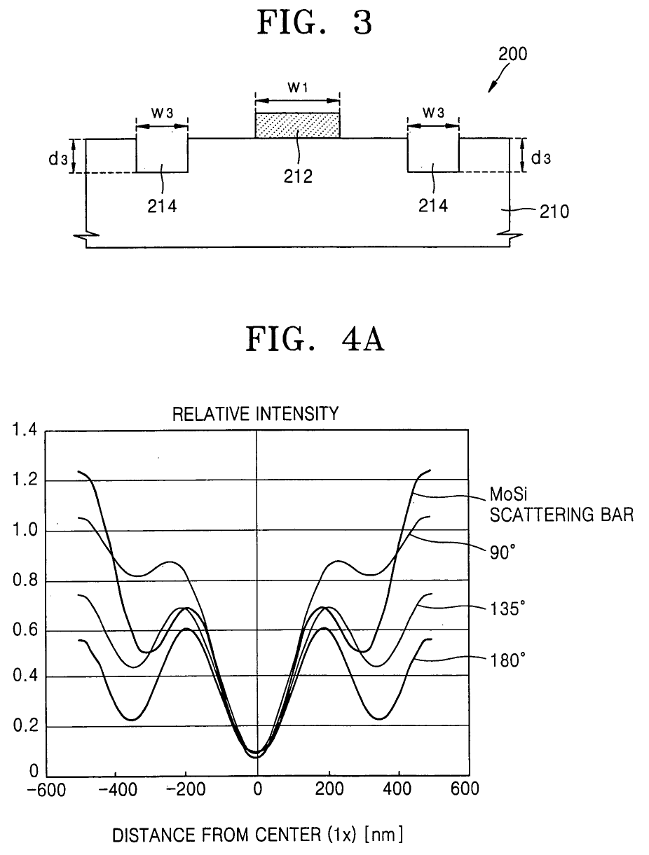

FIG. 3 illustrates a first embodiment of a photo mask 200 according to the present invention. In particular, FIG. 3 shows that portion of the photo mask 200 where the pattern density is low, namely, a region where an isolated pattern 212 is located.

Referring to FIG. 3, the photo mask 200 includes a transparent substrate 210, a main pattern 212, and scattering bars 214. The substrate 210 is transparent to the light emitted by a light source of an exposure apparatus. For example, the substrate 210 is formed of a transparent material such as quartz. The scattering bars 214 are located on both sides of the main pattern 212 and are formed by etching the transparent substrate 210.

The image of the main pattern 212 is transferred to photosensitive material, i.e., a photoresist layer, on a wafer or the like during exposure and developing steps of the photolithography process. In the exposure step, the photoresist layer is exposed to incident rays that have been transmitted by the photo mask. The present invention may be realized as any type of photo mask depending on the shape or material of the main pattern 212 and the pattern(s) adjacent thereto. For example, in the case shown in FIG. 3 in which the main pattern 212 is formed on the transparent substrate 210, the photo mask 200 may be realized as a binary mask (BM) by forming the main pattern 212 of a metal having a transmissivity of roughly 0%, such as chromium (Cr). Alternatively, the photo mask 200 may be realized as a phase shift mask (PSM) by forming the main pattern 212 of a material having a transmissivity of several to several tens of %, such as molybdenum silicide (MoSi). On the other hand, the main pattern 212 may be formed by etching the transparent substrate 210. In this case, the photo mask 200 is realized as a chromeless phase lithography (CPL) mask.

As is conventional, per se, the image of the scattering bars 214 are not transferred to a photoresist layer by incident rays during the exposure and developing steps. However, unlike in conventional photo masks, the scattering bars 214 of the present invention are not formed of an opaque material on the transparent substrate 210. Rather, the scattering bars 214 are formed by etching the transparent substrate 210 over a predetermined width w₃ and to a predetermined depth d₃ at several locations. Accordingly, the pattern of the scattering bars 214 remains intact irrespective of the width or size of the scattering bars 214, i.e., scattering bars 214 formed in this way do not collapse. Therefore, the photo mask 200 of the present invention is very useful in the manufacturing of highly integrated semiconductor devices.

Preferably, the width w₃ of each scattering bar 214 is ½ to 1 times the width we of the main pattern 212, such that the image of the scattering bar 214 is not transferred during the exposure step and such that the scattering bars 214 are easy to manufacture. In addition, the width w₃ and depth d₃ of a scattering bar 214 are selected to limit the phase difference between a ray that is transmitted through the mask at the region of the scattering bar 214 and a ray that is transmitted through the mask at the region of the main pattern 212 to less than 180°. Preferably, this phase difference is in the range of from about 30 to 150°. A phase difference within this range results in moderated destructive interference occurring between the rays that are transmitted through the mask at the region of the scattering bar 214 and the rays that are transmitted through the mask at the region of the main pattern 212. Accordingly, the provision of the scattering bars 214 can increase the depth of focus (DOF) for the exposure process and decrease differences between the actual critical dimension (CD) and the design CD of the feature formed by transferring the image of the main pattern 212 (i.e., an isolated pattern).

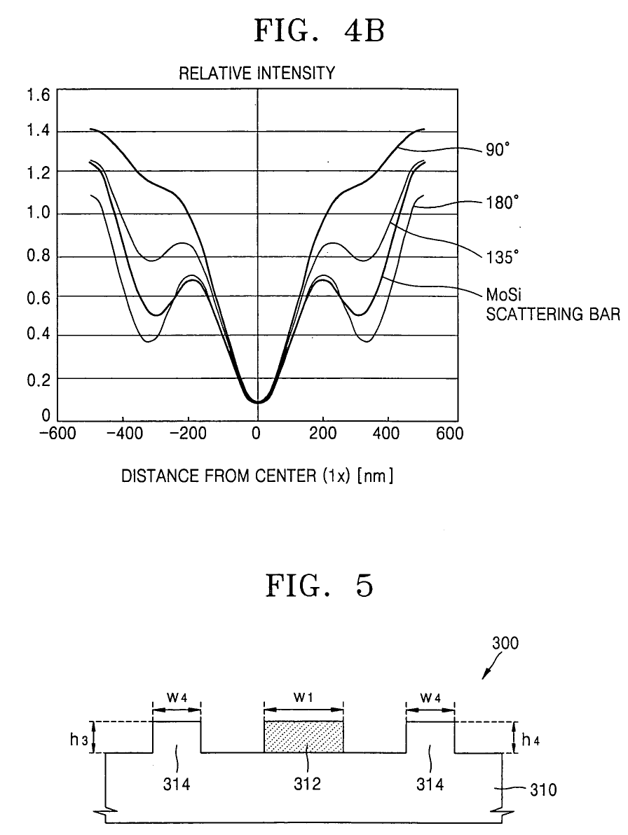

This is evident from the fact that the normalized image log slope (NILS) derived from an aerial image transmitted by the photo mask 200 of the present invention is greater than that derived from an aerial image transmitted by the conventional photo mask 100. In this respect, FIGS. 4A and 4B are graphs showing the relative intensity of aerial images obtained using the photo mask 200 of the present invention and the relative intensity of an aerial image obtained using the conventional photo mask 100. In particular, FIG. 4A shows the case in which the width w₃ of the scattering bar 214 was 140 nm, while FIG. 4B shows the case in which the width w₃ of the scattering bar 214 was 100 nm. On the other hand, both FIGS. 4A and 4B show the case in which the conventional scattering bar 114 of MoSi had a width w₂ of 60 nm. And, the main patterns 112 and 212 of the photo masks 100 and 200 each comprised a strip of MoSi having a width w₁ of 200 nm (the scale of which is 1×, hereinafter).

Also, the results were obtained for photo masks 200 having scattering bars 214 of different depths d₃ for each given width w₃. These depths were selected such that the photo masks 200 induced phase differences of 90°, 135°, and 180°, respectively. As described previously, the phase difference refers to that exhibited between the rays transmitted through the mask at the region of the scattering bar 214 and the rays transmitted through the mask at the region of the main pattern 212.

In addition, the exposure equipment used to obtain the experimental results shown in FIGS. 4A and 4B comprised a KrF light source emitting light having a wavelength of 248 nm, an annular aperture having an inner radius of 0.55 and an outer radius of 0.85, and a lens having a numerical aperture (NA) of 0.7.

The following Tables 1 and 2 show NILS values obtained with reference to FIGS. 4A and 4B, respectively.

TABLE 1

| | Scattering bar of present | | | |
|---|---|---|---|---|
| | invention (w₃ = 140 nm) | | | Conventional scattering bar |
| Phase difference | 90° | 135° | 180° | (w₂ = 60 nm) |
| NILS | 2.53 | 2.33 | 2.20 | 2.28 |

TABLE 2

| | Scattering bar of present | | | |
|---|---|---|---|---|
| | invention (w₃ = 100 nm) | | | Conventional scattering bar |
| Phase difference | 90° | 135° | 180° | (w₂ = 60 nm) |
| NILS | 2.85 | 2.37 | 2.28 | 2.28 |

Referring to Tables 1 and 2, the NILS value obtained in connection with each of the photo masks 200 of the present invention that induced a phase difference of less than 180° was higher than the NILS value obtained in connection with the conventional photo mask 100. In addition, the width w₃ of the scattering bars 214 of the photo masks 200 was greater than the width w₂ of the conventional scattering bar 114. Accordingly, the scattering bar 214 of the photo mask 200 of the present invention can be designed and manufactured with less regard to the resolution limit of the exposure process than can the conventional MoSi scattering bar 114.

FIG. 5 illustrates a second embodiment of a photo mask 300 according to the present invention. In particular, FIG. 5 shows that portion of the photo mask 300 where the pattern density is low, namely, a region where an isolated pattern 214 is located.

Referring to FIG. 5, like the photo mask 200 of the previous embodiment, the photo mask 300 includes a transparent substrate 310, a main pattern 312, and scattering bars 314 formed by etching the transparent substrate 310. However, in this embodiment, the scattering bars 314 constitute a convex pattern that protrudes from a surface of the transparent substrate 310. The main pattern 312 is formed on the same surface from which the scattering bars 314 protrude.

Each scattering bar 314 has a predetermined width w₄ and a height h₄, which establishes a phase difference of less than 180° between the rays transmitted through the mask at the region of the scattering bars 314 and the rays transmitted through the mask at the region of the main pattern 312. As a result, moderated destructive interference occurs between the rays that are transmitted through the mask at the region of the scattering bars 314 and the rays that are transmitted through the mask at the region of the main pattern 312. The NILS value of an aerial image of the transmitted rays is greater than that which is obtained for the conventional photo mask 100.

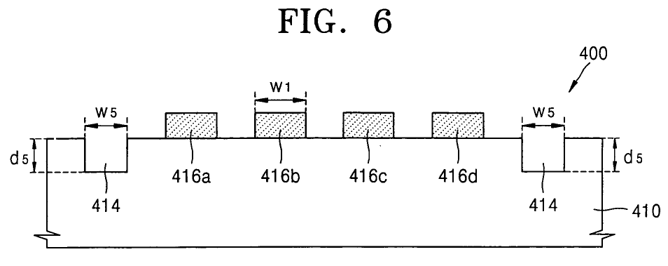

FIG. 6 illustrates a second embodiment of a photo mask 400 according to the present invention. In particular, FIG. 6 shows that portion of the photo mask 400 where the pattern density is low, namely, a region where an isolated pattern 414 is located.

Referring to FIG. 6, the photo mask 400 includes a transparent substrate 410, a main pattern having a plurality of discrete elements 416a through 416d, and scattering bars 414 formed by etching the transparent substrate 410. Although four elements 416a through 416d are illustrated in FIG. 6, the main pattern may have fewer or more than four elements. Also, the scattering bars 414 are formed outside the main pattern, namely, to the side of the outermost elements 416a, 416d of the main pattern.

Each scattering bar 614 has a predetermined width w₅ and depth d₅, which establishes a phase difference of less than 180° between the rays transmitted through the mask at the region of the scattering bars 614 and the rays transmitted through the mask at the region of the main pattern. As a result, moderated destructive interference occurs between the rays that are transmitted through the mask at the region of the scattering bars 614 and the rays that are transmitted through the mask at the region of the main pattern. The NILS value of an aerial image of the transmitted rays is greater than that which is obtained for the conventional photo mask 100.

According to the present invention as described above, the scattering bars of the photo mask are formed by etching the transparent substrate of the mask. Thus, the scattering bars will not collapse even if the CD of the scattering bars is very small in correspondence with a small design rule. Furthermore, the scattering bars can have a greater width than conventional scattering bars; accordingly, the scattering bars can be designed and manufactured with less regard to the resolution limit of the exposure process.

Finally, although the present invention has been particularly shown and described with reference to the preferred embodiments thereof, the present invention is not so limited. Rather, various changes in form and details may be made to the preferred embodiments without departing from the true spirit and scope of the present invention as defined by the following claims.

1. A photo mask for use in transferring an image to photosensitive material during a photolithography process, said photo mask comprising:
a substrate transparent to exposure light of a given wavelength;
a main pattern located at an intermediate region of the transparent substrate, the main pattern having an image dedicated to be transferred to the photosensitive material by rays of the exposure light transmitted by the photomask during the photolithography process; and
scattering bars located to the sides of the intermediate region outside the main pattern, each of said scattering bars being constituted by a recess in the transparent substrate or a protrusion of the transparent substrate, and
wherein the dimensions of said scattering bars are such that the image thereof is not transferred to the photosensitive material by the rays of the exposure light transmitted by the photomask during the photolithography process, and
such that a phase difference of less than 180° is induced between the rays transmitted through the photo mask at the region of the scattering bars and the rays transmitted through the mask at the intermediate region where the main pattern is located.

2. The photo mask of claim 1, wherein the phase difference is in the range of 30 to 150°.

3. The photo mask of claim 1, wherein the width of each of the scattering bars is between ½ and 1 times the width of the main pattern.

4. The photo mask of claim 1, wherein each of the scattering bars is constituted by only one said recess or protrusion.

5. The photo mask of claim 1, wherein the main pattern is an isolated pattern consisting of one element, and the scattering bars are disposed on both sides of the main pattern.

6. The photo mask of claim 1, wherein the main pattern is a pattern of a plurality of discrete elements including elements in the form of lines at outer portions thereof, respectively, and each of the scattering bars is formed adjacent a respective one of the line elements at a said outer portion of the main pattern.

7. The photo mask of claim 1, wherein the main pattern is of chromium (Cr) or molybdenum silicide (MoSi).

8. The photo mask of claim 1, wherein each of the scattering bars is constituted by a recess in said substrate.

9. The photo mask of claim 1, wherein each of the scattering bars is a constituted by a portion of the substrate that protrudes from a surface thereof constituting the intermediate region where said main pattern is located.

10. A method of manufacturing a photomask for use in transferring an image to photosensitive material during a photolithography process, said photo mask comprising:
determining conditions of an exposure step in the photolithography process including the wavelength of exposure light that is to be transmitted by the photomask onto the photosensitive material;
providing a substrate that is transparent to the exposure light;
forming a main pattern at an intermediate region of the transparent substrate, the main pattern having an image dedicated to be transferred to the photosensitive material by rays of the exposure light transmitted by the photomask during the photolithography process;
forming scattering bars at opposite sides of the intermediate region by etching the transparent substrate,
said forming of the scattering bars comprising dimensioning the scattering bars such that destructive interference will prevent the image of the scattering bars from being transferred to the photosensitive material by the rays of the exposure light transmitted by the photomask during the photolithography process, and
such that a phase difference of less than 180° will be induced between the rays of the exposure light transmitted through the photo mask at the region of the scattering bars and the rays of the exposure light transmitted through the mask at the intermediate region where the main pattern is located.

11. The method of claim 10, wherein the phase difference is in the range of 30 to 150°.

12. The method of claim 10, wherein said dimensioning of the scattering bars comprises forming the width of each of the scattering bars to be between ½ and 1 times the width of the main pattern.

13. The method of claim 10, wherein said forming of the main pattern comprises forming at least one element of chromium (Cr) or molybdenum silicide (MoSi) on the substrate.

14. The method of claim 10, wherein said forming of the scattering bars comprises etching recesses in the transparent substrate at respective sides of the intermediate region, whereby the recesses in the transparent substrate constitute the scattering bars.

15. The method of claim 10, wherein said forming of the scattering bars comprises etching the transparent substrate while leaving portions of the substrate that protrude from a surface thereof constituting the intermediate region, whereby the protruding portions of the substrate constitute said scattering bars, and wherein said main pattern is subsequently formed at said surface.
